(19) United States
(12) Patent Application Publication
(10) Pub. No.: US 2026/0177614 A1
(43) Pub. Date: Jun. 25, 2026

(54) Device and Method for Diagnosis of the Same

(71) Applicant: Taiwan Semiconductor Manufacturing Company, Ltd., Hsinchu (TW)

(72) Inventors: Ankita Patidar, Hsinchu (TW); Sandeep Goel, Hsinchu (TW)

(21) Appl. No.: 19/176,327

(22) Filed: Apr. 11, 2025

Related U.S. Application Data
(60) Provisional application No. 63/736,223, filed on Dec. 19, 2024.

(51) Int. Cl. G01R 31/3185; G01R 31/3183

(52) U.S. Cl. CPC G01R 31/318536; G01R 31/318328; G01R 31/318392

(57) ABSTRACT

A device includes a scan chain and a device circuit. The scan chain includes a plurality of sequential elements and a diagnostic hardware circuit. The sequential elements are connected in series and grouped into a plurality of segments. The diagnostic hardware circuit includes a plurality of circuit components, each connected to one sequential element of a respective segment. The diagnostic hardware circuit identifies a defective segment of the scan chain during a diagnostic mode. Test pattern data is serially shifted through the scan chain to isolate the faulty sequential element of the defective segment during the diagnostic mode. The device circuit is connected to the scan chain, performs one or more circuit functions, and generates functional data that is sequentially shifted through the scan chain during a functional mode.

### CROSS-REFERENCE TO RELATED APPLICATION

The present application claims priority to U.S. Provisional Application No. 63/736,223, filed Dec. 19, 2024, the contents of which are incorporated by reference herein in their entirety.

### BACKGROUND

Integrated circuit (ICs) may employ scan chain to facilitate fault detection of their own flip-flops. For example, a scan chain may include a plurality of multiplexers, each connected to a respective flip-flop. The flip-flops and the multiplexers constitute the scan chain, enabling operation of the IC in two distinct modes: a functional mode for normal circuit operation and a diagnostic mode that helps in isolating one or more faulty flip-flops. In the functional mode, the flip-flops sequentially shift functional data generated by a device circuit, propagating it through the scan chain via their data inputs. This functional data is then provided as an output for further processing. During the diagnostic mode, test patterns (predefined sequences of data) are shifted into the scan chain through the scan inputs of the flip-flops. The resulting responses are shifted out and analyzed to determine whether each flip-flop is functioning correctly.

### BRIEF DESCRIPTION OF THE DRAWINGS

Aspects of the present disclosure are best understood from the following detailed description when read with the accompanying figures:

FIG. 1 is a schematic block diagram illustrating an exemplary device in accordance with various embodiments of the present disclosure;

FIG. 2 is a schematic block diagram illustrating another exemplary device in accordance with various embodiments of the present disclosure;

FIG. 3 is a schematic block diagram illustrating another exemplary device in accordance with various embodiments of the present disclosure;

FIG. 4 is a schematic block/circuit diagram illustrating another exemplary device in accordance with various embodiments of the present disclosure;

FIG. 5 is a schematic block/circuit diagram illustrating another exemplary device in accordance with various embodiments of the present disclosure;

FIG. 6 is a schematic block/circuit diagram illustrating another exemplary device in accordance with various embodiments of the present disclosure;

FIG. 7 is a flowchart of an exemplary method for diagnosing stuck-at faults in a device in accordance with various embodiments of the present disclosure;

FIG. 8 is a flowchart of an exemplary method for diagnosing transition delay faults in a device in accordance with various embodiments of the present disclosure;

FIG. 9 is a schematic block/circuit diagram illustrating another exemplary device in accordance with various embodiments of the present disclosure;

FIG. 10 is a schematic block/circuit diagram illustrating another exemplary device in accordance with various embodiments of the present disclosure;

FIG. 11 is a schematic block/circuit diagram illustrating another exemplary device in accordance with various embodiments of the present disclosure;

FIG. 12 is a flowchart of an exemplary method for diagnosing stuck-at faults in a device in accordance with various embodiments of the present disclosure;

FIG. 13 is a flowchart of an exemplary method for diagnosing transition delay faults in accordance with various embodiments of the present disclosure;

FIG. 14 is a schematic block diagram illustrating another exemplary device in accordance with various embodiments of the present disclosure;

FIG. 15 is a schematic block diagram illustrating another exemplary device in accordance with various embodiments of the present disclosure;

FIG. 16 is a schematic block diagram illustrating another exemplary device in accordance with various embodiments of the present disclosure;

FIG. 17 is a schematic block diagram illustrating another exemplary device in accordance with various embodiments of the present disclosure;

FIG. 18 is a schematic block diagram illustrating another exemplary device in accordance with various embodiments of the present disclosure; and

FIG. 19 is a flowchart illustrating an exemplary method for manufacturing a device in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

A device, e.g., an integrated circuit (IC), may employ a hardware diagnostic solution that, in some instances, may be entirely or mostly hardware based. In some example, a bidirectional scan chain includes a diagnostic hardware circuit component (e.g., multiplexer), each connected to a respective flip-flop of the IC, resulting in equal number of flip-flops and multiplexers. This approach can result in significant cell area overhead of, e.g., about 2% to about 3%, adversely impacting power, performance, and area (PPA). To address these issues, certain systems and methods described herein implement a hybrid diagnostic approach that combines hardware and software solutions to reduce the number of multiplexers fewer than the number of flip-flops. For example, sequential elements (e.g., flip-flops) of a scan chain can be divided or grouped into a plurality of segments and a diagnostic hardware circuit component (e.g., a multiplexer) is connected to one (e.g., the first) flip-flop of each segment. Such an approach can significantly reducing area overhead to, e.g., about 1%, minimizing the impact on PPA without compromising fault isolation precision.

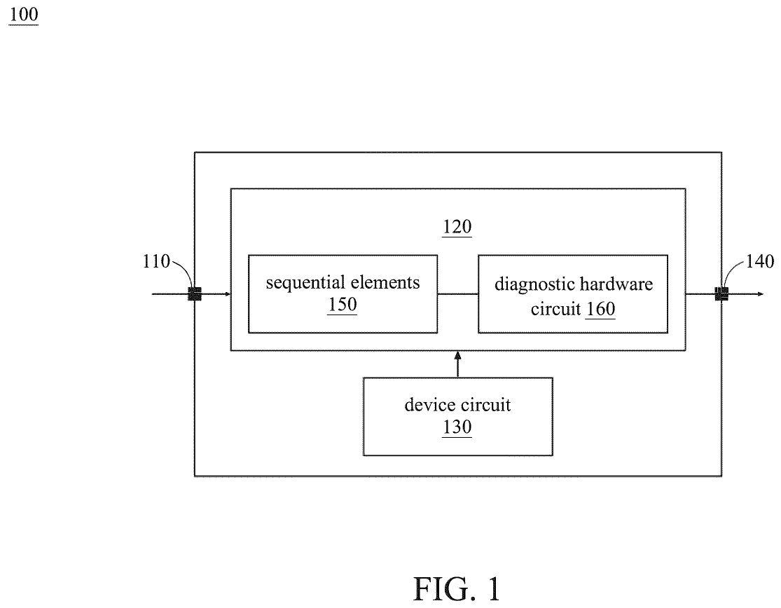

FIG. 1 is a schematic block diagram illustrating an exemplary device 100 in accordance with various embodiments of the present disclosure. In FIG. 1, the example device 100 includes an input terminal 110, one or more scan chains 120, a device circuit 130, and an output terminal 140. In certain embodiments, the device 100 is an integrated circuit (IC), such as a central processing unit (CPU), a memory device (e.g., random access memory or RAM), an analog IC (e.g., operational amplifier, voltage regulator, analog-to-digital converter, and the like), a package IC (e.g., system-on-chip or SoC, an application-specific IC or ASIC, any other suitable package ICs, or a combination thereof).

The input and output terminals 110, 140 are accessible external to the device 100, allowing the device 100 to interact with external test equipment or other devices. The scan chain 120 is connected between the input and output terminals 110, 140 and includes a plurality of sequential elements 150 and a diagnostic hardware circuit 160. The sequential elements 150 are connected in a serial manner and sequentially shift data therethrough to the output terminal 140. The data may be received from the input terminal 110 or the device circuit 130. In this exemplary embodiment, the sequential elements 150 are organized into a plurality of segments, each including a predetermined number of sequential elements. In certain embodiments, the sequential element 150 is in the form of a storage element, such as a D-type flip-flop, JK, SR, or T flip-flops, latches, shift registers, RAM cells, or any other suitable storage elements, or a combination thereof.

The diagnostic hardware circuit 160 facilitates identification of one or more faulty sequential elements in the scan chain 120. It includes a plurality of circuit components, each connected to one sequential element of a respective segment, e.g., the first sequential element. These circuit components manage the flow of data through the scan chain 120, ensuring proper operation in both functional and diagnostic modes. In some embodiments, the circuit component includes a multiplexer. Different configurations of the circuit component are contemplated in other embodiments.

The device circuit 130 is connected to the scan chain 120, performs one or more circuit functions during the normal (or functional) mode of the device 100, and generates functional data that is sequentially shifted through the scan chain 120 as part of the normal circuit operation. In certain embodiments, the device circuit 130 includes various logic circuits that carry out core operations of the device 100, such as data processing, signal routing, or arithmetic computations. These operations support the overall functionality and performance of the device 100, while the scan chain 120 provides test access to the sequential elements during the diagnostic mode.

From the above description, because each circuit component (e.g., multiplexer) is connected to one (e.g., the first) sequential element of a respective segment in the scan chain 120, area overhead is significantly reduced. Software-based tools, such as automated test pattern generation (ATPG), further analyze scan chain patterns to enhance diagnostic resolution. This hybrid approach minimizes PPA impact while maintaining a high level of fault isolation accuracy, as will be described further below.

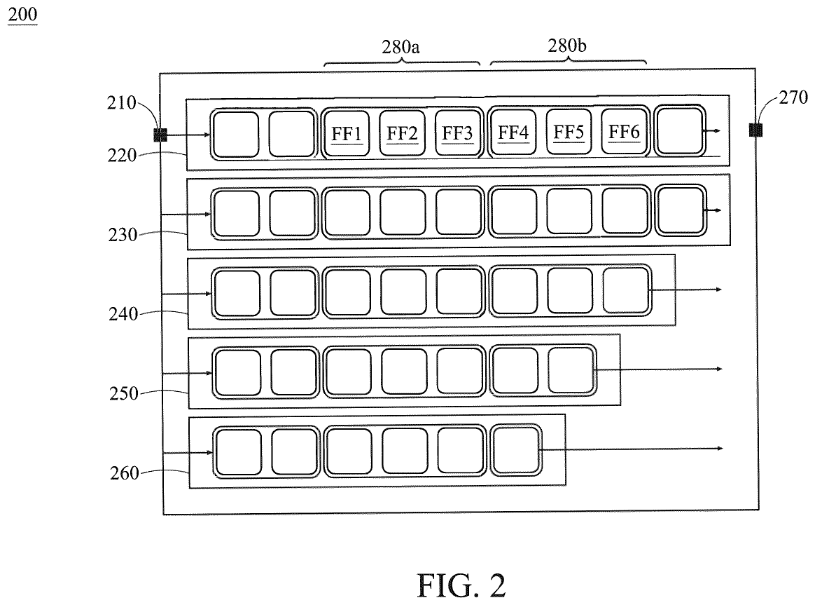

In at least one embodiment, the device 100 may include more than one scan chain. For example, FIG. 2 is a schematic block diagram illustrating another exemplary device 200 in accordance with various embodiments of the present disclosure. In FIG. 2, the example device 200 (e.g., device 100) includes an input terminal 210, a plurality of scan chains 220-260, and an output terminal 270. Each scan chain (e.g., scan chain 210) is connected between the input and output terminals (e.g., 210, 270) and includes a plurality of sequential elements (e.g., FF1-FF6) and a diagnostic hardware circuit (e.g., diagnostic hardware circuit 160 of FIG. 1). The sequential elements are connected in a serial manner and sequentially shift data from one sequential element to the next with each clock cycle, thereby propagating data from the first to the last sequential element of the scan chain. In this exemplary embodiment, the sequential elements of each scan chain 220-260 are divided (or grouped) into a plurality of segments (e.g., 220, 230), each including a predetermined number of sequential elements (e.g., three).

The diagnostic hardware circuit 160 facilitates identification of faulty sequential elements, in a manner that will be described in detail further below. It includes a plurality of circuit components, each connected to the first sequential element (e.g., FF1, FF4) of a respective segment (e.g., 280a, 280b).

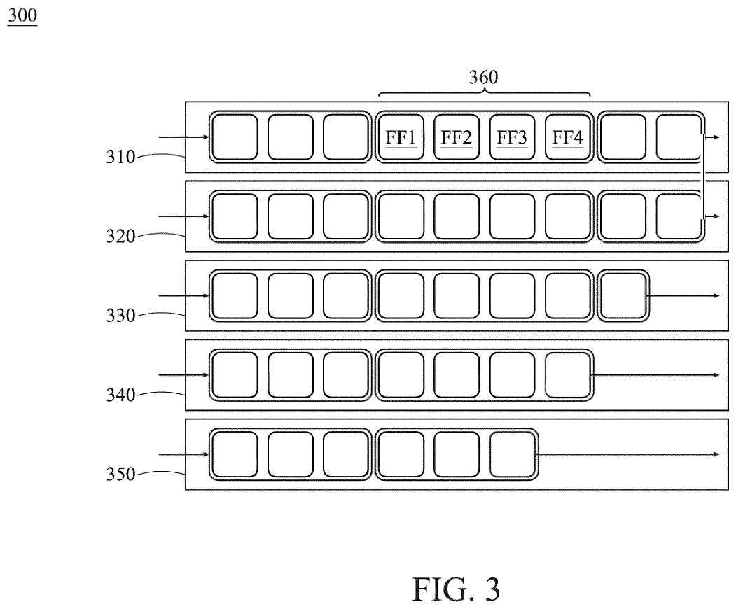

Although the scan chain of the device 200 is exemplified with segments 280a, 280b, each having three sequential elements (e.g., FF1-FF3, FF4-FF6), it should be understood that, after reading this disclosure, the number of sequential elements in a segment of a scan chain may be increased or decreased as desired. For example, FIG. 3 is a schematic block diagram illustrating another exemplary device 300 in accordance with various embodiments of the present disclosure. In FIG. 3, the example device 300 (e.g., device 100) includes a plurality of scan chains (e.g., 310-350), each includes a plurality of sequential elements (e.g., FF1-FF4). The sequential elements of each scan chain 310-350 are connected in a serial manner and shift data sequentially, with each clock cycle transferring data from one sequential element to the next. In this exemplary embodiment, the sequential elements of a scan chain 310-350 are grouped into a plurality of segments. In this exemplary embodiment, at least one of the segments includes four sequential elements (FF1-FF4).

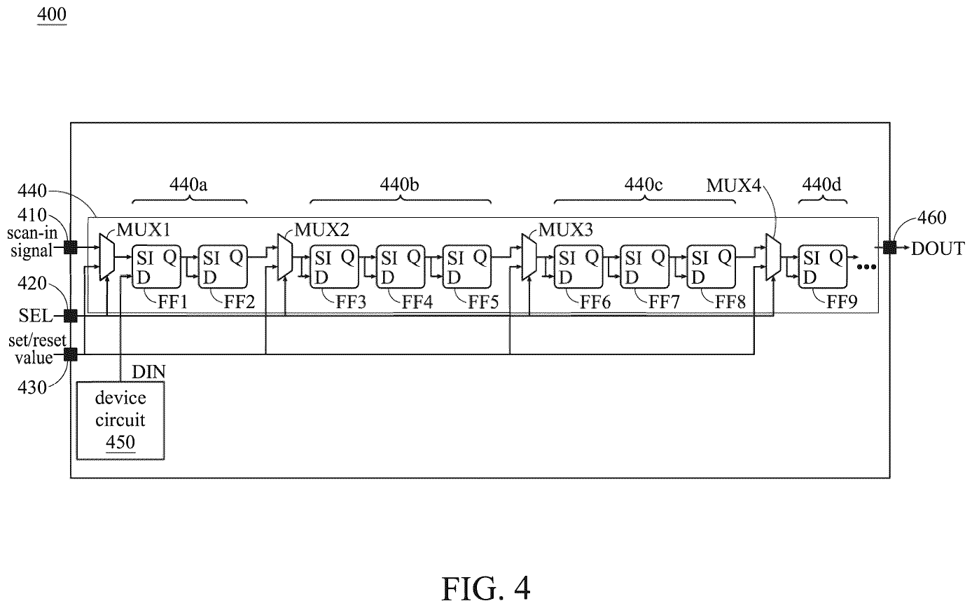

FIG. 4 is a schematic block/circuit diagram illustrating another exemplary device 400 in accordance with various embodiments of the present disclosure. In FIG. 4, the example device 400 (e.g., device 100-300) includes first, second, and third input terminals 410-430, one or more scan chains (e.g., scan chain 440), a device circuit 450, and an output terminal 460. The input and output terminals 410-430, 460 are accessible external to the device 400.

The scan chain 440 is connected between the input and output terminals 410-430, 460 and includes a plurality of sequential elements (FF1-FF9) and a diagnostic hardware circuit (e.g., diagnostic hardware circuit 160 of FIG. 1). The sequential elements (FF1-FF9) are connected in a serial manner, allowing data to be shifted sequentially from one sequential element to the next with each clock cycle, propagating from the first to the last sequential element. The scan chain receives either a scan-in signal from the input terminal 410 or a data signal (DIN) from the device circuit 450. In this exemplary embodiment, the scan chain 440 are divided into a plurality of segments (e.g., segments 440a-440d). In some embodiments, at least two of the segments 440a-440d have the same number of sequential elements. In other embodiments, the number of sequential elements may differ among segments 440a-440d.

The diagnostic hardware circuit 160 facilitates identification of faulty sequential elements. For example, the diagnostic hardware circuit 160 includes a plurality of circuit components (MUX1-MUX4), each connected to one of the sequential elements of a respective segment (440a-440d), e.g., the first sequential element (FF1, FF3, FF6, FF9). In particular, the circuit component (MUX1) is connected between the input terminal 410 and the sequential element (FF1). Similarly, the circuit component (MUX2-MUX4) connects the last sequential element (FF2, FF5, FF8) of one segment to the first sequential element (e.g., FF3, FF6, FF9) of the next segment.

The device circuit 450 is connected to the scan chain 440 and performs one or more circuit functions during the normal (or functional) mode of the device 400. It generates a data signal (DIN) that is serially shifted through the scan chain 440 as part of the circuit's normal operation. In certain embodiments, the device circuit 450 includes various logic components that carry out core functions, such as data processing, signal routing, or arithmetic computations. These functions support the overall operation of the device 400, while the scan chain 440 enables access to the sequential elements (FF1-FF9) during diagnostic mode.

In an exemplary design process of the device 400, the sequential elements (FF1-FF9) are connected to each other in a serial manner to form the scan chain 400. The scan chain 440 is then grouped into a plurality of segments (e.g., segments 440a-440d). Each segment's first sequential element is connected to a respective circuit component (MUX1-MUX4) of the diagnostic hardware circuit 160.

In an exemplary normal (or functional) mode, the data signal (DIN) generated by the device circuit 450 is received at the data input (D) terminals of the sequential elements (FF1-FF9), is latched on the rising edge of the clock signal, and is serially shifted through their outputs (Q). The output (DOUT) is provided at the output terminal 460 for further processing, such as amplification and decoding.

In an exemplary first diagnostic mode, the diagnostic hardware circuit 160 performs a coarse-grain diagnosis to identify a defective segment of the scan chain 440. Once the defective segment is identified, a diagnostic software tool performs a finer-grain diagnosis to pinpoint the faulty sequential element of the segment identified as defective by the diagnostic hardware circuit 160. For example, during the coarse-grain diagnosis, each circuit component (MUX1-MUX4) receives a select signal (SEL) from the input terminal 420 having, e.g., a logical high (‘1’), enabling the device 400 to perform the coarse-grain diagnosis. A set/reset value is applied to the input terminal 430 and is serially shifted through the scan chain 440 via the scan inputs (SI) of the sequential elements (FF1-FF9). The set/reset value is then latched in the sequential elements (FF1-FF9) and propagated through their outputs (Q). The propagated set/reset value is provided at the output terminal 460 for further analysis or observation.

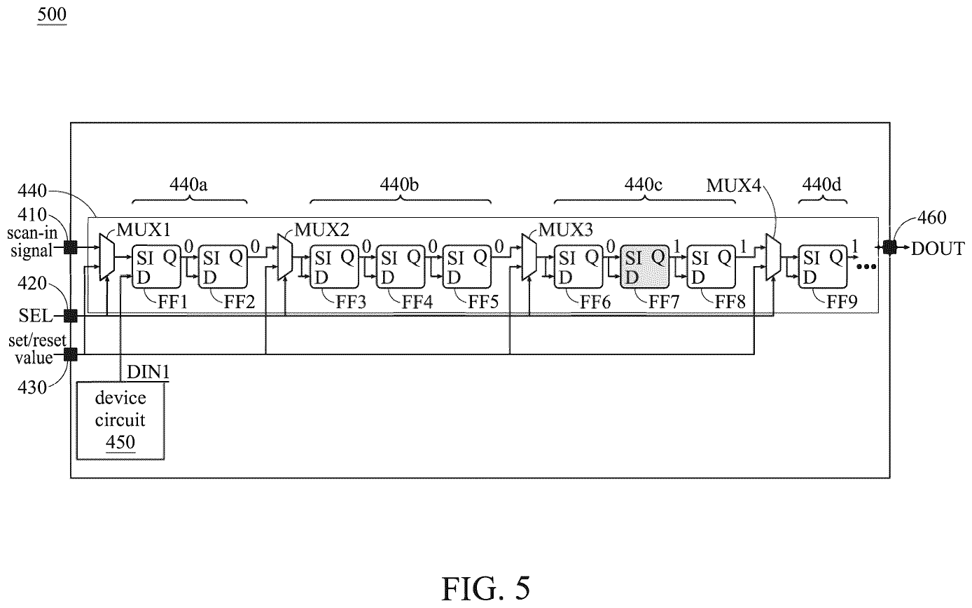

For example, if the set/reset value at the input terminal 430 is all logical ‘0’s (to detect stuck-at-1 faults) or all logical ‘1’s (for stuck-at-0 faults) and if all the sequential elements (FF1-FF9) are functioning correctly, the set/reset value remains intact as it propagates through the scan chain 440. As a result, the output signal (DOUT) at the output terminal 460 matches the expected pattern. However, if one or more sequential elements (FF1-FF9) are faulty, the set/reset value is altered as it propagates through the scan chain 440. For example, FIG. 5 is a schematic block/circuit diagram illustrating another exemplary device 500 in accordance with various embodiments of the present disclosure. In FIG. 5, the sequential element (FF7) is stuck-at-1 and thus generates an output (Q) of logical ‘1’ regardless of its scan input (SI). This results in an altered output (e.g., DOUT=000000111) at the output terminal 460.

The presence and position of the corrupted bits (e.g., logical ‘1’s) in the output pattern (DOUT) indicate the defective segment (e.g., segment 440c) and that one or more of its sequential elements (FF7, FF8) may be faulty. For example, the output signal (DOUT) suggests that the sequential element (FF7) is stuck at logical ‘1’ and that the sequential element (FF8) may also be faulty, making it a candidate for further diagnosis.

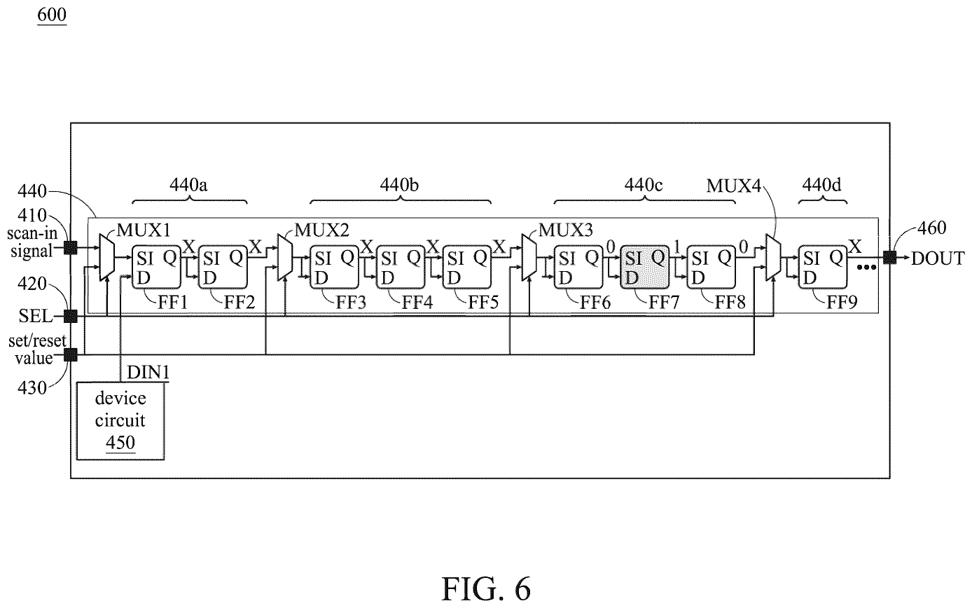

To isolate the faulty sequential element(s) in the segment 440c, A finer-grain diagnosis is then performed by the diagnostic software tool performs on the candidate sequential elements (FF7, FF8) identified by the coarse-grain diagnosis. For example, FIG. 6 is a schematic block/circuit diagram illustrating another exemplary device 600 in accordance with various embodiments of the present disclosure. In FIG. 6, each circuit component (MUX1-MUX4) receives a select signal (SEL) (e.g., a logical low ‘0’) and the diagnostic software tool generates a scan-in signal (or test pattern data) fed to the input terminal 410. This test pattern data is sequentially shifted through the scan chain 440 via the scan inputs (SI) of the sequential elements (FF1-FF9), and provided as a data output (DOUT) at the output terminal 460.

If the sequential element (FF8) generates an expected output, i.e., its output (Q) matches its scan input (SI), it is identified as functional and the sequential element (FF7) is the sole faulty sequential element. Otherwise, if the sequential element (FF8) generates an unexpected output (DOUT), both sequential elements (FF7, FF8) are confirmed as faulty.

In an exemplary second diagnostic mode, similar hardware-software coordination is used to diagnose transition delay faults, such as slow-to-rise (STR) and slow-to-fall (STF) faults. For example, the diagnostic hardware circuit 160 performs a coarse-grain diagnosis to identify a defective segment of the scan chain 440, while the diagnostic software tool performs a finer-grain diagnosis to pinpoint the faulty sequential element in the defective segment. In this mode, each circuit component (MUX1-MUX4) receives a select signal (SEL) with a logical ‘1’ from the input terminal 420. A set/reset value is applied at the input terminal 430 and is serially shifted through the scan chain 440 via the scan inputs (SI) of the sequential elements (FF1-FF9). The set/reset value is latched in the sequential elements and propagates in a serial manner to the output terminal 460 through their outputs (Q).

If all sequential elements (FF1-FF9) are functioning correctly, the transitions in the set/reset value propagate without delay through the scan chain 440, resulting in an output (DOUT) that matches the expected pattern. However, if one or more sequential elements (FF1-FF9) exhibits a transition delay, such as a STR or STF fault, the set/reset value fails to propagate in time. For example, as illustrated in FIG. 5, the sequential element (FF7) exhibits a STR fault. That is, despite receiving a logical ‘0’ to ‘1’ transition at its scan input (SI), its output (Q) fails to rise to logical ‘1’ within the expected timing window. This delay results in a corrupted output (e.g., DOUT=00000011) at the output terminal 460.

The delayed transition in the output pattern helps identify the faulty segment (e.g., 440c) and one or more faulty sequential elements (e.g., FF&, FF8). Specifically, the delayed output from the sequential element (FF7) suggests it has an STR fault, while the sequential element (FF8) is identified as a candidate for further diagnosis.

To isolate the faulty sequential element(s) in the segment 440c, the diagnostic software tool performs a finer-grain diagnosis on the candidates (e.g., FF7, FF8), as identified by the coarse-grain hardware diagnosis. For example, at illustrated in FIG. 6, a scan-in signal (or test pattern data) is applied to the input terminal 410, is sequentially shifted through the scan chain 440 via the scan inputs (SI) of the sequential elements, and is analyzed at the output terminal 460 to check whether the transitions occur as expected.

If the sequential element (FF8) behaves correctly (i.e., its output Q matches its scan-in input (SI), the sequential element (FF7) is confirmed to be the sole faulty sequential element exhibiting an STR fault. However, if the sequential element (FF8) also generates an unexpected output, both the sequential elements (FF7, FF8) are identified to be faulty, each exhibiting a transition delay fault (e.g., STR or STF).

In this exemplary embodiment, the diagnostic software tool includes an automatic test equipment (ATE) and an ATPG that is installed in the ATE and that generates the scan-in signal (or test pattern data) during the finer-grain diagnosis.

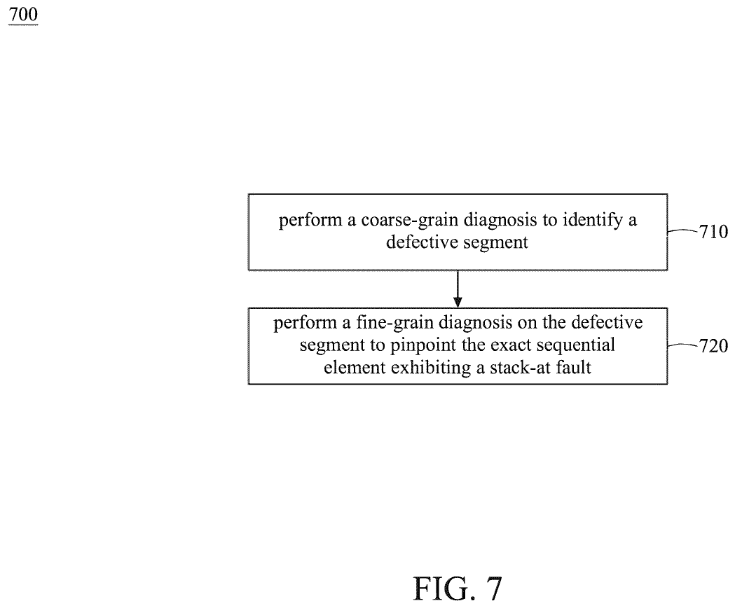

FIG. 7 is a flowchart of an exemplary method 700 for diagnosing stuck-at faults (i.e., STR and STF) in a device (e.g., 100-600) in accordance with various embodiments of the present disclosure. The example method 700 will now be described with further reference to FIGS. 1-6 for ease of understanding. It is understood that the method 700 is applicable to structures other than those of FIGS. 1-6. Further, it is understood that additional operations can be provided before, during, and after the method 700, and some of the operations described below can be replaced or eliminated, in an alternative embodiment of the method 700.

In operation 710, a coarse-grain diagnosis is performed using the diagnostic hardware circuit 160 to identify a defective segment of the scan chain 430. For example, each circuit component (e.g., MUX1-MUX4) receives a select signal (SEL), such as a logical ‘1’, from the input terminal 420, placing the scan chain 440 into hardware-based diagnostic mode. A scan-in signal (or test pattern data) is then applied at the input terminal 410 and is serially shifted through the scan inputs (SI) of the sequential elements (FF1-FF9). Each sequential element (FF1-FF9) latches the test pattern data at its scan input (SI) and shift it through the next sequential element through its output (Q) on each clock cycle. The propagated test pattern data at the output terminal 460 is observed as a data output (DOUT).

The output data (DOUT) may be analyzed to determine whether the test pattern data is altered as it propagates through the scan chain 440. For example, if the test pattern consists entirely of logical ‘0’s (for stuck-at-1 testing) or logical ‘1’s (for stuck-at-0 testing), and if all sequential elements are operating correctly, the data remains intact, and the output (DOUT) matches the input pattern, e.g., a string of logical ‘0’s or ‘1’s.

However, if one or more sequential elements are faulty, the test pattern data is corrupted as it propagates. The altered output (DOUT) may then be used to identify the defective segment. For instance, if the sequential element (FF7) is stuck-at-1, it generates a constant logical ‘1’ at its output (Q) regardless of receiving a logical ‘0’ at its scan input (SI). This causes an unexpected change in the output (e.g., DOUT=000000111) observed at output terminal 460. The position of the transition in the output pattern (DOUT) indicates that segment 440c is defective. The subsequent sequential elements in the same segment (e.g., FF8) may also be considered faulty or candidates for further diagnosis.

In operation 720, a fine-grain diagnosis is carried out using a diagnostic software tool to further evaluate the candidate sequential elements (e.g., FF7, FF8) identified during the hardware-based coarse-grain phase. For example, each circuit component (e.g., MUX1-MUX4) receives a select signal (SEL), such as a logical ‘0’, from the input terminal 420, placing the scan chain 440 into software-based diagnostic mode. The diagnostic software tool generates a set/reset value configured to assess the behavior of each candidate sequential elements (FF7, FF89). This pattern is applied at input terminal 430, shifted through the scan chain 440 via the scan inputs (SI), and the resulting output (DOUT) is analyzed at terminal 460 to determine the faulty sequential element(s).

If a candidate sequential element (e.g., FF8) generates an expected output, i.e., its output (Q) matches its scan input (SI), then the sequential element (FF8) is considered functional, confirming that the sequential element (FF7) is the sole faulty sequential element. Conversely, if the sequential (FF8) generates an unexpected output, it is confirmed as faulty, indicating that both the sequential elements (FF7, FF8) are defective.

From the above description, the diagnostic mode combines a coarse-grain hardware diagnosis with a fine-grain software-based analysis to detect and localize stuck-at faults in the scan chain 440. This hybrid diagnostic approach provides accurate fault isolation while minimizing additional hardware overhead.

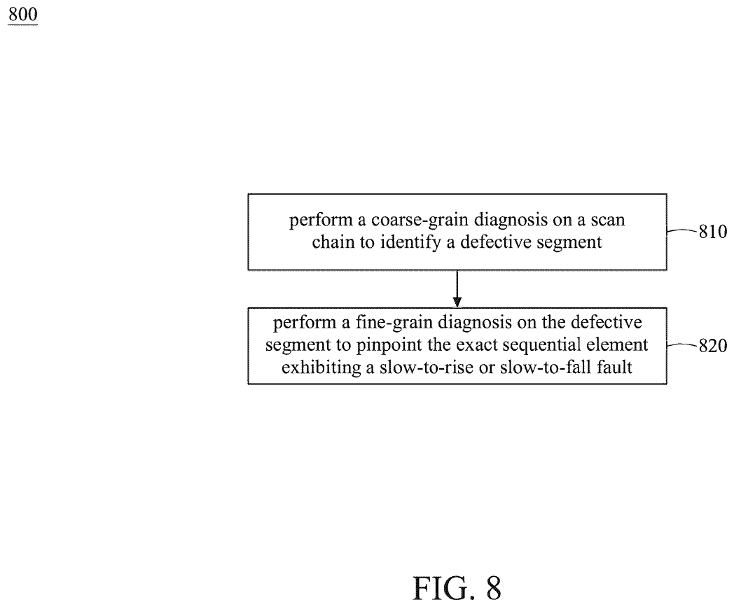

FIG. 8 is a flowchart of an exemplary method 800 for diagnosing transition delay faults, e.g., slow-to-rise (STR) fault or slow-to-fall (STF) fault in a device (e.g., device 100-600) in accordance with various embodiments of the present disclosure. The example method 800 will now be described with further reference to FIGS. 1-6 for ease of understanding. It is understood that the method 800 is applicable to structures other than those of FIGS. 1-6. Further, it is understood that additional operations can be provided before, during, and after the method 800, and some of the operations described below can be replaced or eliminated, in an alternative embodiment of the method 800.

In operation 810, a coarse-grain diagnosis is performed on the device 400 using the diagnostic hardware circuit 160 to identify a defective segment of the scan chain 440. For example, each circuit component (MUX1-MUX4) receives a select signal (SEL), e.g., a logical ‘1’, from the input terminal 420, switching the scan chain 440 to hardware-based diagnostic mode. A scan-in signal (or test pattern data) is applied at the input terminal 420 and is serially shifted through the scan inputs (SI) of the sequential elements (FF1-FF9). Each sequential element latches the test pattern data at its scan input (SI) and propagates it to the next sequential element through its output (Q). The propagated test pattern data is then observed at the output terminal 460 as a data output (DOUT). In this exemplary embodiment, the test pattern data induces transitions (e.g., ‘0’ to ‘1’ transitions or ‘1’ to ‘0’ transitions) configured to detect transition delay faults.

The output data (DOUT) may be analyzed to determine whether delays or failures in the transitions as the test pattern data propagates through the scan chain 440. For example, if all the sequential elements (FF1-FF9) are functioning correctly, the transitions occur without delay, and the output (DOUT) matches the expected pattern at the output terminal 460.

However, if a sequential element is faulty, the expected transition may be delayed or fail to occur. The altered or delayed output (DOUT) can then be analyzed to identify the defective segment of the scan chain 440. For example, if sequential element (FF7) exhibits an STR fault, it fails to transition from logical ‘0’ to ‘1’ at its output (Q) despite receiving a logical ‘1’ at its scan input (SI). This delay or failure results in an incorrect output pattern, such as 000000011, at the output terminal 460. Similarly, if the sequential element (FF7) exhibits an STF fault, it fails to transition from logical ‘1’ to ‘0’ at its output (Q), resulting in an incorrect output pattern (e.g., DOUT=111111100). The position of the faulty transition in the output (DOUT) indicates that the error originates in the segment 440c. Other sequential elements in the same segment (such as sequential element (FF8) may also be faulty.

In operation 820, a finer-grain diagnosis is performed using a diagnostic software tool to evaluate the candidate sequential elements (FF7, FF8) identified during the coarse-grain diagnosis to pinpoint the exact faulty sequential element(s). For example, each circuit component (MUX1-MUX4) receives a select signal (SEL), e.g., a logical ‘0’, from the input terminal 420, switching the scan chain 440 to software-based diagnostic mode. The diagnostic software tool generates a set/reset value (or test pattern data) to induce transitions in the candidate sequential element (e.g., FF7, FF8). The test pattern data is applied to the input terminal 430, is sequentially shifted through the scan chain 440 via the scan inputs (SI), and observed at the output terminal 460.

If a candidate sequential element (e.g., FF8) generates the expected output, i.e., it completes the intended transition (‘0’ to ‘1’ or ‘1’ to ‘0’) within the expected timing window, it is determined to be functioning correctly, confirming that the preceding sequential element (e.g., FF7) is the sole faulty sequential element. Conversely, if the sequential element (FF8) exhibits delayed or incorrect transitions, both sequential elements (FF7, FF8) are diagnosed as faulty.

From the above description, the method 800 combines coarse-grain hardware diagnosis with fine-grain software analysis to identify and localize STR and STF transition faults in the scan chain. This hybrid approach ensures precise fault localization with minimal hardware overhead.

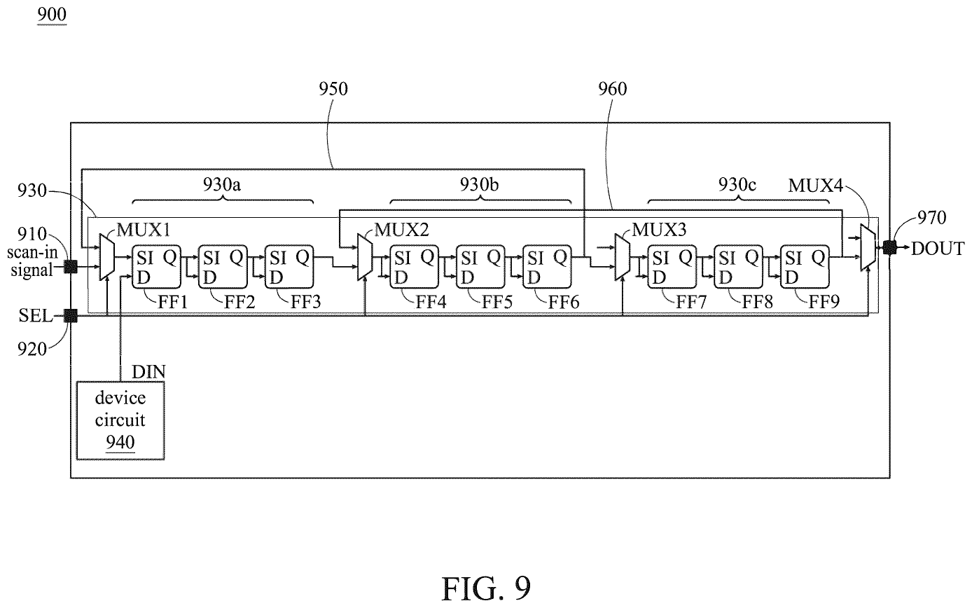

FIG. 9 is a schematic block/circuit diagram illustrating another exemplary device 900 in accordance with various embodiments of the present disclosure. In FIG. 9, the example device 900 (e.g., device 100-300) includes first and second input terminals 910, 920, one or more scan chains (e.g., scan chain 930), a device circuit 940, a plurality of feedback loops 950, 960, and an output terminal 970. The input and output terminals 910, 920, 970 are accessible external to the device 900.

In at least one embodiment, the scan chain 930 is a bi-directional scan chain. For example, the scan chain 930 is connected between the input and output terminals 910, 920, 950 and includes a plurality of sequential elements (FF1-FF9) and a diagnostic hardware circuit (e.g., diagnostic hardware circuit 160 of FIG. 1). The sequential elements (FF1-FF9) are connected in a serial manner and sequentially shift data from one sequential element to the next with each clock cycle, propagating from the first to the last sequential element (FF1-FF9) or forward-shift operation of the scan chain 930. The scan chain 930 is grouped into a plurality of segments (e.g., segments 930a-930c). In some embodiments, at least two of the segments 930a-930c have the same number of sequential elements. In other embodiment, they may have different numbers of sequential elements.

The diagnostic hardware circuit 160 facilitates identification of faulty sequential elements. For example, the diagnostic hardware circuit 160 includes a plurality of circuit components (MUX1-MUX3), each connected to one of the sequential elements (e.g., the first sequential element) of a respective segment 930a-930c. In particular, the circuit component (MUX1) is connected between the input terminal 910 and the first sequential element (FF1). Similarly, the circuit component (MUX2, MUX3) connects the last sequential element (FF3, FF6) of one segment 930a, 930b to the first sequential element (FF4, FF7) of the next segment 930b, 930c. In this exemplary embodiment, the diagnostic hardware circuit 160 further includes a circuit component (MUX4) connected between the last sequential element (FF9) and the output terminal 970.

The feedback loop 950, 960 is connected between an output of one segment 930a, 930b and the input of a previous segment 930a, 930b, enabling backward-shift operation of the scan chain 930. For example, the feedback loop 950 connects the output (Q) of the sequential element (FF6) to an input of the circuit component (MUX1), while the feedback loop 960 connects the output (Q) of the sequential element (FF9) to an input of the circuit component (MUX2).

The device circuit 940 is connected to the scan chain 930, performs one or more circuit functions during the functional mode of the device 900, and generates functional data (DIN) that is serially shifted through the scan chain 930. In certain embodiments, the device circuit 940 includes one or more logic circuits (e.g., logic gates, arithmetic circuits, multiplexers/demultiplexers, encoders/decoders, comparators, any other data generators, or combinations thereof) that support the overall functionality and operation of the device 900.

In an exemplary design process of the device 900, the sequential elements (FF1-FF9) of each scan chain 930 are connected to each other in a serial manner. The scan chain 930 is then divided or grouped into a plurality of segments 930a-930c. Next, each circuit component (MUX1-MUX3) is connected to one (e.g., the first) sequential element (FF1, FF4, FF7) of a respective segment 930a-930c. Finally, the feedback loop 950, 960 is connected between an output of one segment 930a, 930b and the input of a previous segment 930a, 930b.

In an exemplary normal (or functional) mode, functional data (DIN) generated by the device circuit 940 propagates through the scan chain 930. In this mode, each circuit component (MUX1-MUX3) receives a select signal (SEL), e.g., a logical ‘0’, from the input terminal 920, enabling the device 900 to operate in the functional mode. The functional data (DIN) is received at the data inputs (D) of the sequential elements (FF1-FF9), is latched on clock edges, and is serially propagated through their outputs (Q). The resulting data is then provided at the output terminal 970 for further processing, such as amplification and/or decoding.

In an exemplary first diagnostic (test) mode, the diagnostic hardware circuit 160 performs a forward-shift diagnosis to identify a defective segment of the bi-directional scan chain 930. This is followed by a backward-shift diagnosis to locate the faulty sequential element in the segment identified as defective during the forward-shift diagnosis. During the forward-shift diagnosis, each circuit component (MUX1-MUX4) receives a select signal (SEL), e.g., a logical ‘1’, from the input terminal 910, enabling operation of the device 900 in the forward-shift diagnostic mode. A scan-in signal (or test pattern data) is applied at the input terminal 910 and is serially shifted through the scan chain 930 via the scan inputs (SI) of the sequential elements (FF1-FF9). The test pattern data is latched in the sequential elements (FF1-FF9) and is sequentially shifted through their outputs (Q). The resulting data is then provided to the output terminal 4970 for observation and analysis.

When the scan-in signal at the input terminal 910 includes entirely of logical ‘0’s (to test stuck-at-1 faults) and when all the sequential elements (FF1-FF9) are functioning correctly, the test pattern data remains intact as it propagates through the sequential elements (FF1-FF9). As a result, the output signal (DOUT) at the output terminal 970 matches the input, e.g., all logical ‘0’s.

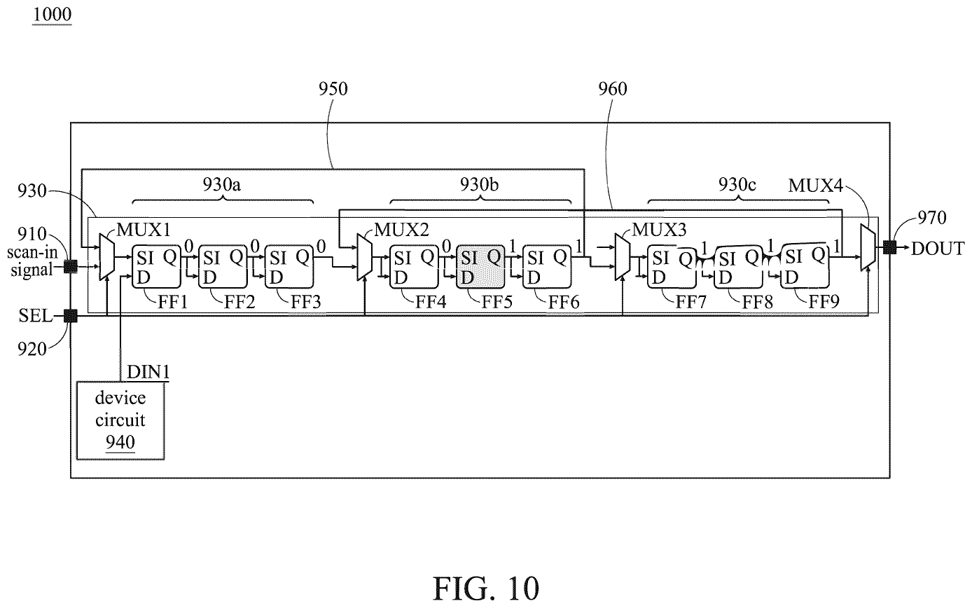

However, if one or more sequential elements (FF1-FF9) are faulty, the test pattern data may be altered as it propagates through the scan chain 930. For example, FIG. 10 is a schematic block/circuit diagram illustrating another exemplary device 1000 in accordance with various embodiments of the present disclosure. In FIG. 10, the sequential element (FF5) may be stuck-at-1 and outputs logical ‘1’, regardless of its scan input (SI). This results in an altered output (e.g., DOUT=000011111) at the output terminal 970. The presence of the unexpected logical ‘1’s and their position in the output (DOUT) indicate that the segment 930b is defective and one or more of its sequential elements (FF5, FF6) may be faulty. In particular, the output pattern (DOUT) suggests that the sequential element (FF5) is stuck-at-1 and that the sequential element (FF6) may also be a candidate for further diagnosis.

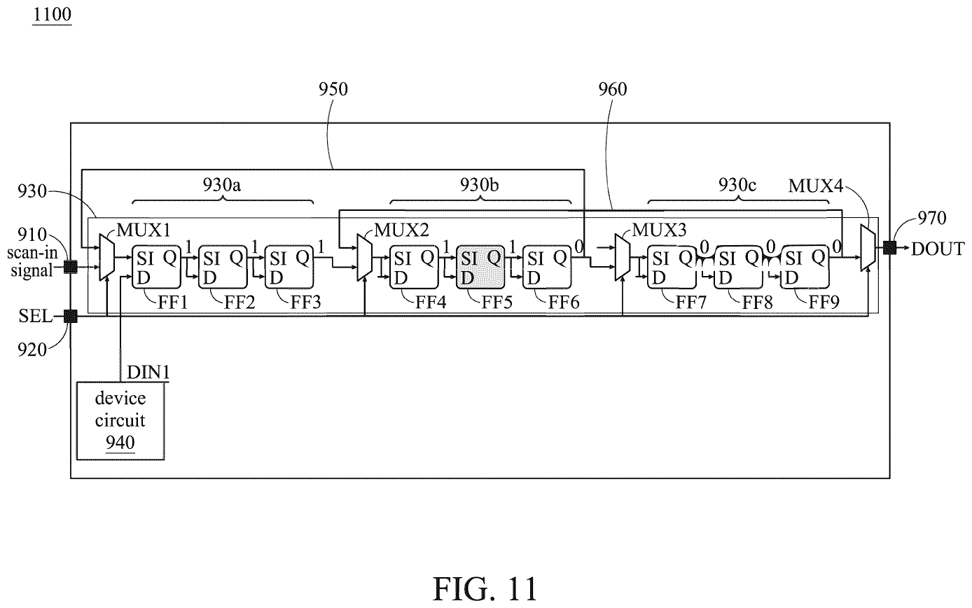

To isolate the faulty sequential element(s) of the segment 930c, a backward-shift diagnosis is performed on the candidates (FF5, FF6) identified by the forward-shift diagnosis. For example, FIG. 11 is a schematic block/circuit diagram illustrating another exemplary device 1100 in accordance with various embodiments of the present disclosure. In FIG. 11, each circuit component (MUX1-MUX4) receives a select signal (SEL), e.g., a logical ‘1’, enabling operation of the device 900 in the backward-shift diagnostic mode. A scan-in signal (or test pattern data) is applied at the input terminal 920. The circuit components (MUX1-MUX4) and the associated feedback loops 950, 960 redirect the test pattern data to the last sequential element (FF9) of the scan chain 930. This redirection initializes the backward-shift operation, i.e., the test pattern data propagates from the last to the first sequential element. On each clock cycle, the output (Q) of a sequential element becomes the scan input (SI) for the preceding sequential element.

As the backward-shift progresses, the test pattern data moves toward to the first sequential element (FF1). The circuit components (MUX1-MUX4), in combination with the feedback loops 950, 960, route the final result from the first sequential element (FF1) to the output terminal 970 for evaluation. If the sequential element (FF6) generates an expected output, i.e., its output (Q) matches its scan input (SI), it is determined that the sequential element (FF6) is functioning correctly, confirming that the sequential element (FF5) is the sole faulty sequential element. Otherwise, if the sequential element (FF6) generates an unexpected output (DOUT), both sequential elements (FF5, FF6) are identified as faulty.

In an exemplary second diagnostic mode, the diagnostic hardware circuit 160 performs forward-shift diagnosis to identify a defective segment of the bi-directional scan chain 930, followed by a backward-shift diagnosis to isolate the faulty sequential element in segment identified as defective by the forward-shift diagnosis. During the forward-shift diagnosis, each circuit component (MUX1-MUX4) receives a select signal (SEL), e.g., a logical ‘1’, switching the device 900 into diagnostic mode. A scan-in signal (or test pattern data) is applied at the input terminal 920 and is serially shifted through the scan chain via the scan inputs (SI) of the sequential elements (FF1-FF9). The test pattern data is latched in the sequential elements and propagates serially through their outputs (Q) to the output terminal 970.

If all sequential elements (FF1-FF9) are functioning correctly, the transitions in the test pattern data propagate through the scan chain 930 without delay, resulting in an output pattern (DOUT) at the output terminal 970 that matches the expected pattern. However, if one or more sequential elements (FF1-FF9) exhibit a transition delay fault, such as a STR or STF fault, the test pattern data will not propagate as expected. For example, as illustrated in FIG. 10, the sequential element (FF5) exhibits a STR fault. Despite receiving a logical ‘0’ to ‘1’ transition at its scan input (SI), the output (Q) of the sequential element (FF7) fails to rise to logical ‘1’ within the expected time. This transition delay results in an incorrect output pattern (e.g., DOUT=000000011) to appear at the output terminal 970.

The incorrect output pattern (DOUT) and the position of the delayed transition indicate that the segment 930b, which includes the sequential element (FF5), is defective may include one or more faulty sequential elements (e.g., FF6). In particular, the delayed transition at the sequential element (FF5) suggests a STR fault, with the sequential element (FF6) may also be considered a candidate for further diagnosis.

To isolate the faulty sequential element(s) in the defective segment 930c, the diagnostic hardware circuit reconfigures the device 1000 to perform a backward-shift diagnosis. For example, as illustrated in FIG. 11, the device 1000 receives a scan-in signal (or test pattern data) at its input terminal 920 for evaluating the transitions at the sequential elements (FF5, FF6). The circuit components (MUX1-MUX4) and the feedback loops 950, 960 redirect the test pattern data to the last sequential element (FF9), initiating backward data propagation. The test pattern data then propagates in reverse, from the sequential element (FF9) to the sequential element (FF1), with each sequential element's output (Q) serving as the input (SI) of the preceding sequential element. The test pattern data then reaches the sequential element (FF1) and is routed to the output terminal 950 for evaluation.

If the sequential element (FF6) generates the expected output, i.e., its output (Q) matches its scan input (SI), it is determined that the sequential (FF6) is functioning correctly and the sequential element (FF5) is confirmed to be the sole faulty sequential element, exhibiting a STR fault. Conversely, if the sequential element (FF6) generates an unexpected output, then both the sequential elements (FF5, FF6) are identified as faulty, each exhibiting transition delay fault (STR or STF).

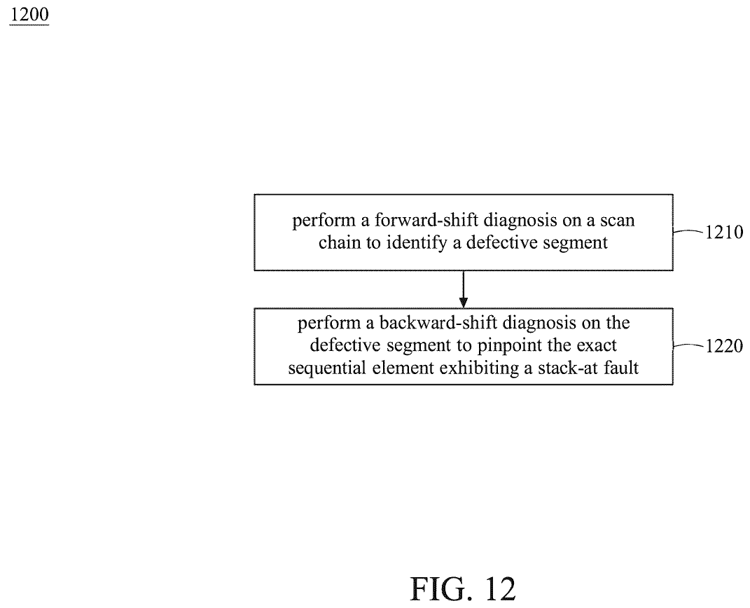

FIG. 12 is a flowchart of an exemplary method for diagnosing stuck-at faults in a device (e.g., 100-300, 900-1100) in accordance with various embodiments of the present disclosure. The example method 1200 will now be described with further reference to FIGS. 1-3 and 9-11 for ease of understanding. It is understood that the method 1200 is applicable to structures other than those of FIGS. 1-3 and 9-11. Further, it is understood that additional operations can be provided before, during, and after the method 1200, and some of the operations described below can be replaced or eliminated, in an alternative embodiment of the method 1200.

In operation 1210, a forward-shift diagnosis is performed on the device 900 to identify a defective segment of the scan chain 930. For example, each circuit component (MUX1-MUX4) receives a select signal (SEL), e.g., a logical ‘1’, from the input terminal 920, switching the scan chain 930 to forward-shift diagnostic mode. A scan-in signal (or test pattern data) is applied at the input terminal 910 and is serially shifted through the scan inputs (SI) of the sequential elements (FF1-FF9). Each sequential element (FF1-FF9) latches the test pattern data and propagates it to the next sequential element through its output (Q). The resulting data is then provided as a data output (DOUT) at the output terminal 970 via the last circuit component (MUX4).

The output data (DOUT) may be analyzed to detect any alterations in the test pattern data as it propagates through the scan chain 930. For example, if the test pattern data includes entirely of logical ‘0’s (for stuck-at-1 testing) or logical ‘1’s (for stuck-at-0 testing) and if all sequential elements (FF1-FF9) are functioning correctly, the test pattern data (DIN2) remains intact or an unaltered. This results in the expected data output (DOUT) pattern, e.g., all logical ‘0’s, at the output terminal 970.

However, if a sequential element is faulty, the test pattern data is altered as it propagates through the scan chain 930. The resulting output (DOUT) may be analyzed to identify the defective segment of the scan chain 930. For example, if the sequential element (FF5) is stuck-at-1, it outputs a logical ‘1’ even when receiving a logical ‘0’ at its scan input (SI). This results in an altered output pattern (DOUT), such as 000011111, at the output terminal 970. The presence and position of unexpected logical ‘1’s in the output (DOUT) indicate that the fault lies in the segment 930b. Additionally, other sequential elements (FF6) in the segment 930b may also be faulty.

In operation 1220, a backward-shift diagnosis is performed among the candidate sequential elements (e.g., FF5, FF6) identified during the forward-shift diagnosis to isolate the exact faulty sequential element(s). For example, each circuit component (MUX1-MUX4) receives a select signal (SEL), e.g., a logical ‘0’, from the input terminal 920, switching the scan chain 930 to backward-shift diagnostic mode. A scan-in signal (or test pattern data) is applied at the input terminal 910. The diagnostic hardware circuit 160 reconfigures the scan chain 930 to backward-shift operation. The circuit components (e.g., MUX1-MUX4) and feedback loops 950 and 960 reroute the test pattern data to the last sequential element (FF9). The test pattern data then propagates in reverse through the scan chain 930, i.e., from FF9 to FF1, where each sequential element's output (Q) serves as the scan input (SI) for the preceding sequential element. Once the data reaches the sequential element (FF1), it is routed to the output terminal 970 for analysis.

If a candidate sequential element (e.g., FF6) generates an expected output, i.e., its output (Q) matches its scan input (SI), it is determined to be functioning correctly. This confirms the sequential element (FF5) is the sole faulty sequential element with a stuck-at fault. Conversely, if the candidate sequential element (FF6) generates an unexpected output, it is confirmed that both the sequential elements (FF5, FF6) are faulty.

By combining forward and backward-shift diagnoses, the method 1200 identifies and localizes faults in the scan chain 930. The forward-shift diagnosis provides coarse-grain localization by identifying the defective segment, while the backward-shift diagnosis enables fine-grain isolation of the exact faulty sequential element(s). This dual approach ensures precise fault localization with minimal hardware overhead.

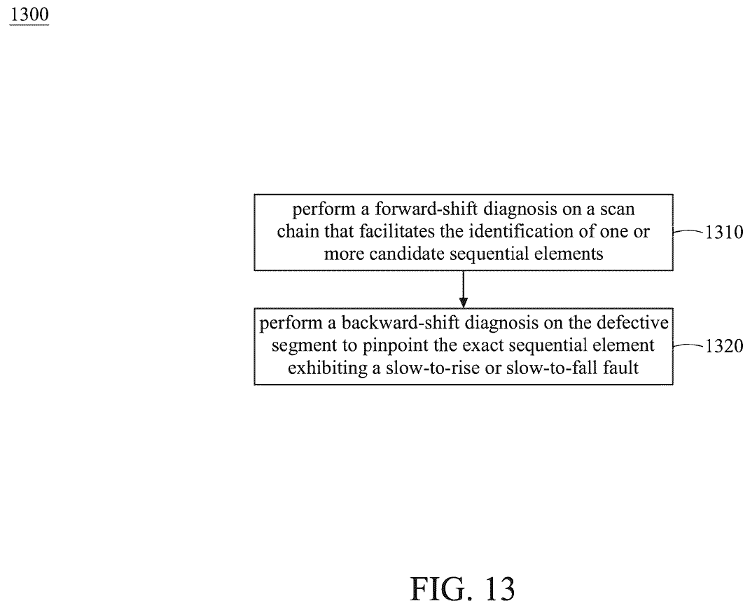

FIG. 13 is a flowchart of an exemplary method 1300 for diagnosing transition delay faults, e.g., STR fault or STF fault in a device 100-300, 900-1100 in accordance with various embodiments of the present disclosure. The example method 1300 will now be described with further reference to FIGS. 1-3 and 9-11 for ease of understanding. It is understood that the method 1300 is applicable to structures other than those of FIGS. 1-3 and 9-11. Further, it is understood that additional operations can be provided before, during, and after the method 1300, and some of the operations described below can be replaced or eliminated, in an alternative embodiment of the method 1300.

In operation 1310, a forward-shift diagnosis is performed on the device 900 to identify a defective segment of the scan chain 930. For example, each circuit component (MUX1-MUX4) receives a select signal (SEL), e.g., a logical ‘1’, from the input terminal 920, switching the scan chain 930 to forward-shift diagnostic mode. A scan-in signal (or test pattern data) is applied at the input terminal 910 and is serially shifted through the scan inputs (SI) of the sequential elements (FF1-FF9). Each sequential element latches the test pattern data and propagates it through its output (Q) to the next sequential element. The resulting data is then provided as a data output (DOUT) at the output terminal 970 via the circuit component (MUX4). In this exemplary embodiment, the test pattern data induces transitions (e.g., ‘0’ to ‘1’ for STR testing or ‘1’ to ‘0’ for STF testing).

The output data (DOUT) may be analyzed to detect delays or failures in the expected transitions as the test pattern data propagates through the scan chain 930. For example, if all sequential elements (FF1-FF9) are functioning correctly, the induced transitions propagate without timing violations, resulting in an unaltered output (DOUT) at the output terminal 970. However, if a sequential element exhibits a transition delay fault, the output pattern (DOUT) is altered or delayed.

The altered data output (DOUT) can be analyzed to identify the defective segment of the scan chain 930. For example, if the sequential element (FF5) exhibits an STR fault, it fails to transition from ‘0’ to ‘1’ at its output Q despite receiving a ‘1’ at its scan input SI. This results in an incorrect pattern (e.g., DOUT=000000011). Similarly, if the sequential element (FF7) has an STF fault, it fails to transition from ‘1’ to ‘0’, resulting in an output (DOUT), e.g., 111111100. The position of the failing transition in output (DOUT) helps locate the faulty segment, e.g., segment 930b. Additional elements within that segment, such as the sequential element (FF6), may also be considered candidates for further analysis.

In operation 1320, a backward-shift diagnosis is performed on the candidate sequential elements (e.g., FF5, FF6) identified during the forward-shift phase. For example, each circuit component (MUX1-MUX4) receives a select signal (SEL), e.g., a logical ‘0’, from the input terminal 920, switching the scan chain 930 to backward-shift diagnostic mode. A scan-in signal (or test pattern data is applied at input terminal 910. The diagnostic hardware circuit 160 reconfigures the scan chain 930 to enable backward-shift mode by routing the test data pattern through circuit components (e.g., MUX1-MUX4) and feedback loops 950, 960 to the last sequential element (FF9). The backward-shift operation propagates the test pattern data from the last sequential element (FF9) to the first sequential element (FF1), with each sequential element's output (Q) serving as the scan input (SI) for the preceding element. Once the test pattern data (DIN3) reaches the sequential element (FF1), it is routed to the output terminal 970 as data output (DOUT) for evaluation.

If the candidate sequential element (e.g., FF6) generates the expected output, i.e., its output (Q) matches its scan input (SI), it is determined to be operating correctly. This confirms that the sequential element (FF5) is the sole faulty sequential element, exhibiting a transition delay fault such as STR or STF. Conversely, if the sequential element (FF6) generates an unexpected output, both the sequential elements (FF5, FF6) are confirmed to be faulty.

By combining forward- and backward-shift diagnoses, the method 1300 identifies and localizes slow-to-rise and slow-to-fall faults in the bidirectional scan chain 930. The forward-shift diagnosis provides coarse-grain localization by identifying the defective segment, while the backward-shift diagnosis enables fine-grain isolation of the exact faulty sequential element(s). This dual diagnostic approach ensures precise fault localization with minimal hardware overhead.

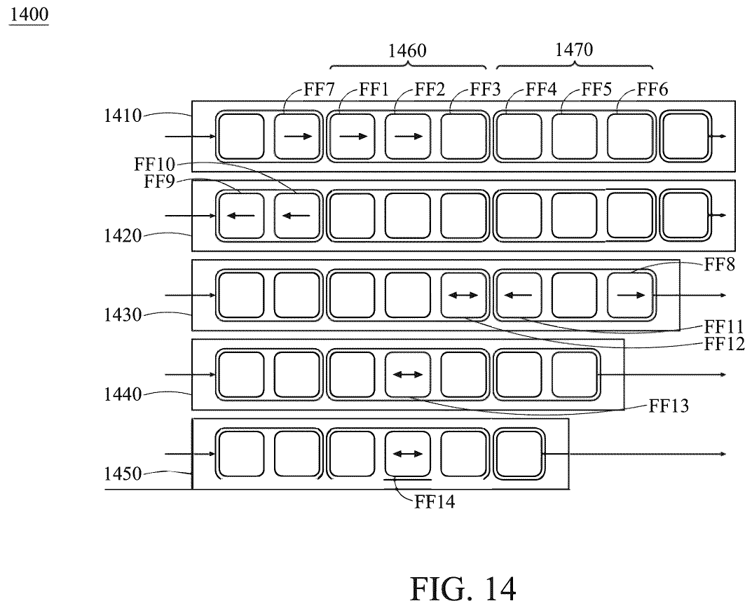

FIG. 14 is a schematic block diagram illustrating another exemplary device 1400 in accordance with various embodiments of the present disclosure. In FIG. 14, the example device 1400 includes a plurality of scan chains 1410-1450 and a diagnostic hardware circuit (e.g., diagnostic hardware circuit 160 of FIG. 1). Each scan chain (e.g., scan chain 1410) includes a plurality of sequential elements (e.g., sequential elements FF1-FF6). These sequential elements are grouped into a plurality of segments (e.g., segments 1460, 1470). The diagnostic hardware circuit 160 includes a plurality of circuit components (e.g., multiplexers MUX1-MUX4 of FIGS. 4 and 9), each connected to one sequential element (e.g., sequential element FF1, FF4) of a respective segment (1460, 1470).

In this exemplary embodiment, one or more sequential elements are assigned with at least one user-defined constraint. These constraints are applied to maintain timing dependencies, logical order, or placement constraints within the scan chain 1410-1450. For example, the sequential element (FF2, FF3, FF1) that follows the sequential element (FF1, FF2, FF7), as indicated by a forward arrow, may be designated as a “don't move” sequential element. This constraint specifies that the position of the sequential element (e.g., FF2, FF3, FF1) in the scan chain 1410, 1430 remains fixed.

Similarly, the sequential element (FF9, FF12) that precedes another sequential element (e.g., FF10, F11), as indicated by a backward arrow, may be also designated as a “don't move” sequential element. This constraint specifies that the position of the sequential element (FF9, FF12) in the scan chain 1420, 1430 remains fixed. Furthermore, the sequential elements preceding and following the sequential element (FF12-FF14), as indicated by a bi-directional arrow, may be also designated as a “don't move” sequential element. This constraint specifies that the positions of these “don't move” sequential elements in the scan chain 1430-1450 remain fixed.

In an exemplary design process of the device 1400, one or more sequential elements (e.g., FF1-FF14) are designated as “don't move” sequential elements to preserve specific timing, logical, or placement constraints. Following this, the sequential elements of each scan chain 1410-1450 are grouped into a plurality of segments based on an area budget, e.g., about 1% of the total area. This area budget determines the segment length, e.g., the number of sequential elements per segment. A circuit component of the diagnostic hardware circuit 160 is then connected to the first sequential element of each segment in the scan chains 1410-1450.

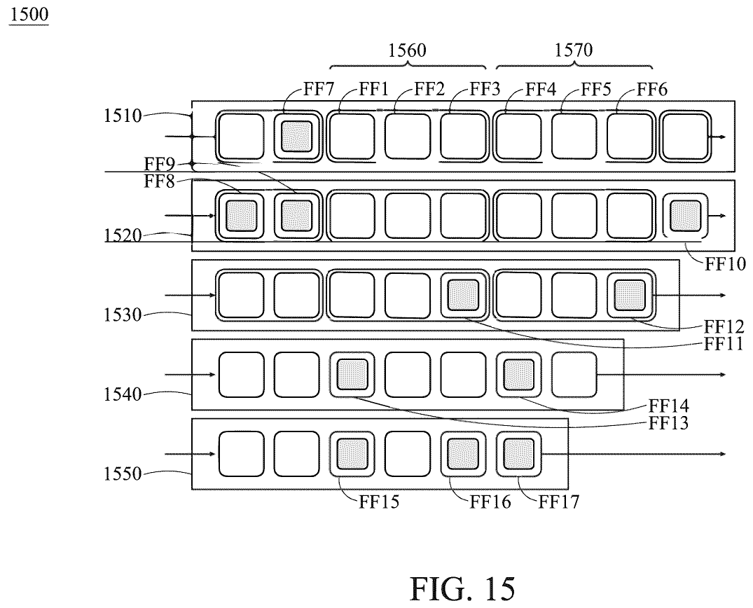

FIG. 15 is a schematic block diagram illustrating another exemplary device 1500 in accordance with various embodiments of the present disclosure. In FIG. 15, the example device 1500 includes a plurality of scan chains 1510-1550 and a diagnostic hardware circuit (e.g., diagnostic hardware circuit 160 of FIG. 1). Each scan chain (e.g., scan chain 1510) includes a plurality of sequential elements (e.g., sequential elements FF1-FF6). These sequential elements are grouped into a plurality of segments (e.g., segments 1560, 1570). The diagnostic hardware circuit 160 includes a plurality of circuit components (e.g., multiplexers MUXn of FIGS. 4 and 9), each connected to the first sequential element (e.g., sequential element FF1, FF4) of a respective segment (1560, 1570).

In this exemplary embodiment, one or more sequential elements are assigned with at least one user-defined constraint, e.g., to maintain timing dependencies, logical order, and/or placement constraints within the scan chains 1510-1550. For example, the sequential element (FF7-FF17) may be designated as a “don't touch” sequential element. This constraint specifies that the sequential element (FF7-FF17) remains free from connection to a circuit component of the diagnostic hardware circuit 160.

In an exemplary design process of the device 1500, one or more sequential elements (e.g., FF7-FF17) are designated as “don't touch” sequential elements. The sequential elements of each scan chain 1510-1550 are then grouped into a plurality of segments based on an area budget, e.g., 1%. This area budget determines the segment length, i.e., the number of sequential elements per segment. In certain embodiments, a circuit component of the diagnostic hardware circuit 160 is connected to the first sequential element of each segment in the scan chains 1510-1550, except for the first sequential element (e.g., FF13-FF15, FF17) that is a “don't touch” sequential element. In such certain embodiments, the diagnostic connection is omitted to comply with the constraint.

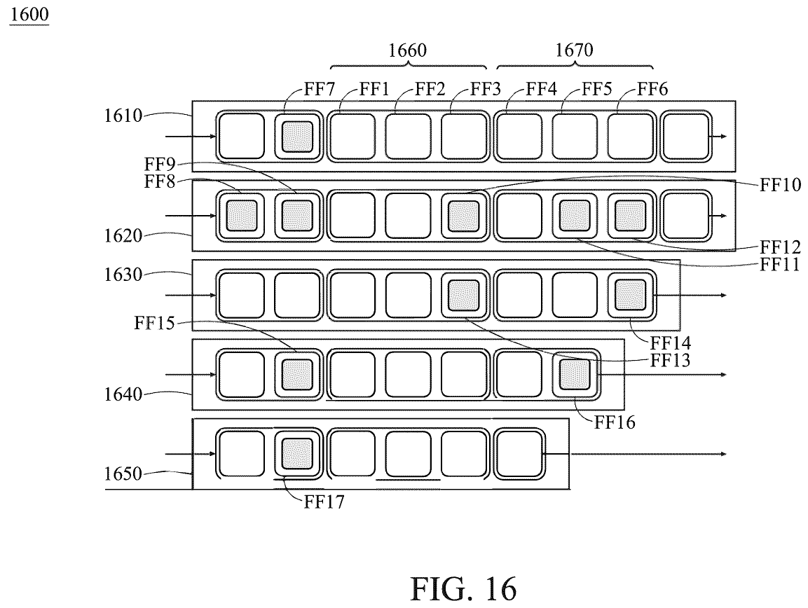

FIG. 16 is a schematic block diagram illustrating another exemplary device 1600 in accordance with various embodiments of the present disclosure. In FIG. 16, the example device 1600 includes a plurality of scan chains 1610-1650 and a diagnostic hardware circuit (e.g., diagnostic hardware circuit 160 of FIG. 1). Each scan chain (e.g., scan chain 1610) includes a plurality of sequential elements (e.g., sequential elements FF1-FF6). These sequential elements are grouped into a plurality of segments (e.g., segments 1660, 1670). The diagnostic hardware circuit 160 includes a plurality of circuit components (e.g., multiplexers MUXn of FIGS. 4 and 9), each connected to the first sequential element (e.g., sequential element FF1, FF4) of a respective segment (1660, 1670).

In this exemplary embodiment, one or more sequential elements are assigned at least one user-defined constraint, e.g., to maintain timing dependencies, logical order, and/or placement constraints within the scan chains 1610-1650. For example, the sequential element (FF7-FF17) may be designated as a “don't touch” sequential element. This constraint specifies that the sequential element (FF7-FF17) remains free from connection to a circuit component of the diagnostic hardware circuit 160.

In an exemplary design process of the device 1600, one or more sequential elements (e.g., FF7-FF17) are designated as “don't touch” sequential elements. The sequential elements of each scan chain 1610-1650 are then grouped into a plurality of segments based on an area budget, e.g., 1% of the total area. This area budget determines the segment length, i.e., the number of sequential elements per segment. If the first sequential element of a segment is designated as a “don't touch” sequential element, it is swapped with another sequential element that is not subject to the constraint. The replacement may be from within the same segment, from a different segment of the same scan chain, or from a different scan chain altogether. A circuit component of the diagnostic hardware circuit 160 is then connected to the (new) first sequential element of each segment across scan chains 1610-1650.

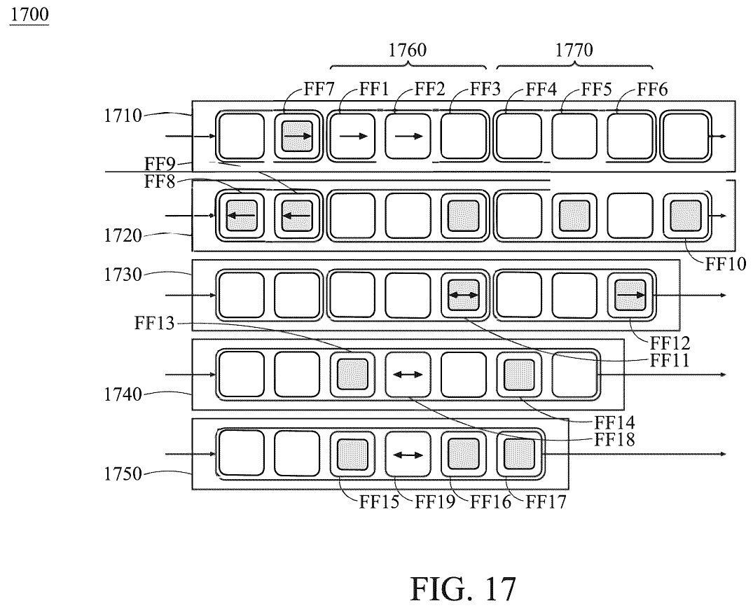

FIG. 17 is a schematic block diagram illustrating another exemplary device 1700 in accordance with various embodiments of the present disclosure. In FIG. 17, the example device 1700 includes a plurality of scan chains 1710-1750 and a diagnostic hardware circuit (e.g., diagnostic hardware circuit 160 of FIG. 1). Each scan chain (e.g., scan chain 1710) includes a plurality of sequential elements (e.g., sequential elements FF1-FF6). These sequential elements are grouped into a plurality of segments (e.g., segments 1760, 1770). The diagnostic hardware circuit 160 includes a plurality of circuit components (e.g., multiplexers MUXn of FIGS. 4 and 9), each connected to the first sequential element (e.g., FF1, FF4) of a respective segment (1760, 1770).

In this exemplary embodiment, one or more sequential elements are assigned with at least one user-defined constraint. These constraints are applied to maintain timing dependencies, logical order, or placement constraints within the scan chain 1710-1750. For example, the sequential element (FF1-FF3) following the sequential element (FF7, FF1, FF2), as indicated with a forward arrow, may be designated as a “don't move” sequential element. This constraint specifies that the position of the sequential element (e.g., FF1-FF3) in the scan chain 1710 remains fixed.

Similarly, the sequential element (FF8) preceding the sequential element (FF9), as indicated with a backward arrow, may be also designated as a “don't move” sequential element. This constraint specifies that the position of the sequential element (FF8) in the scan chain 1720 remains fixed. Furthermore, the sequential elements preceding and following the sequential element (FF11, FF18, FF19), as indicated with a bi-directional arrow, may be also designated as a “don't move” sequential element. This constraint specifies that the positions of these “don't move” sequential elements in the scan chain 1730-1750 remain fixed.

In an exemplary design process of the device 1700, one or more sequential elements (e.g., FF7-FF17) are designated as “don't touch” and “don't move” sequential elements. The sequential elements of each scan chain 1710-1750 are grouped into a plurality of segments based on an area budget, such as 1% of the total area. This area budget determines the segment length, i.e., the number of sequential elements per segment. If the first sequential element of a segment of a scan chain is designated as a “don't touch” sequential element, it is swapped with another sequential element, e.g., from the same segment, from a different segment of the same scan chain, or from a different scan chain that is not designated as “don't touch” or “don't move,” except the replacement sequential element is designated as “don's move.” A circuit component of the diagnostic hardware circuit 160 is then connected to the (new) first sequential element of each segment in the scan chains 1710-1750.

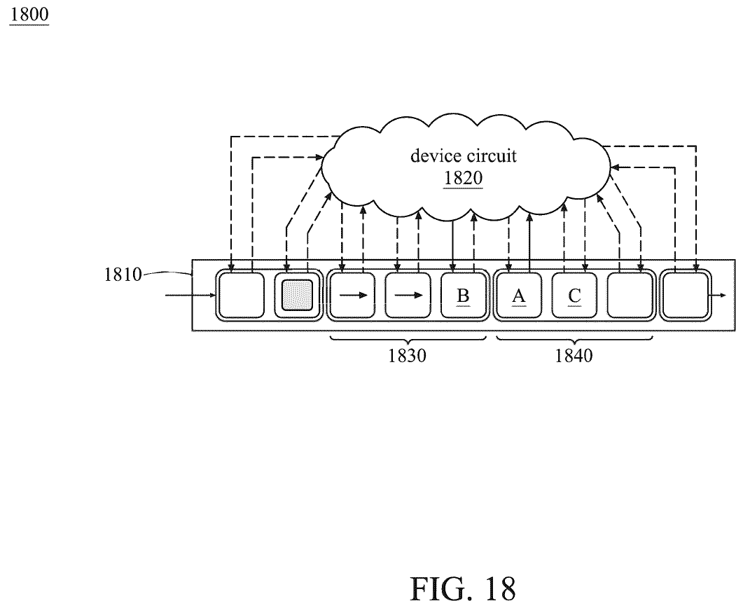

FIG. 18 is a schematic block diagram illustrating another exemplary device 1800 in accordance with various embodiments of the present disclosure. In FIG. 18, the example device 1800 includes a scan chain 1810 and a device circuit 1820. The scan chain 1810 includes a plurality of sequential elements (e.g., A, B, C) and a diagnostic hardware circuit (e.g., diagnostic hardware circuit 160 of FIG. 1). The sequential elements are grouped into a plurality of segments (e.g., 1830, 1840).

In this exemplary embodiment, although the physical scan chain order is such that the sequential element (B) precedes the sequential element (A), while the sequential element (C) follows the sequential element (A), the functional data paths differ from the scan order. For example, the output of the sequential element (C) is connected to the input of the sequential element (A), whereas the output of the sequential element (A) is connected to the input of the sequential element (B). Such an arrangement avoids placing functionality dependent sequential elements (A, B) in the same segment while also ensuring that the sequential element (A) appears after the sequential element (B) in the scan chain. That is, in functional logic, the output of the sequential element (A) drives the input of the sequential element (B), but in the scan chain order, the sequential element (B) precedes the sequential element (A).

This reordering addresses a limitation in a software-based diagnosis. For example, when two sequential elements with a functional dependency are located in the same segment, signal propagation between them can obscure the actual fault location, making it difficult for the software-based diagnosis to identify the faulty element. By placing the driven sequential element (B) before the driving sequential element (A) in scan order and assigning them at different segments (1830, 1840), false fault candidates are minimized and fault isolation is improved.

The diagnostic hardware circuit 160, applied to the first sequential element of each segment, facilitates in identifying the faulty segment and the fault type (e.g., stuck-at or transition delay faults). The hardware may include logic components such as multiplexers (e.g., MUX1-MUX4 of FIGS. 4 and 9). The device circuit 1820 is connected to the scan chain 1810 and operates during normal mode to generate functional data. By combining hardware-based coarse diagnosis with scan-pattern-driven software analysis, the approach balances diagnosis resolution and area cost, and enables accurate fault localization even in the presence of complex logic dependencies between sequential elements.

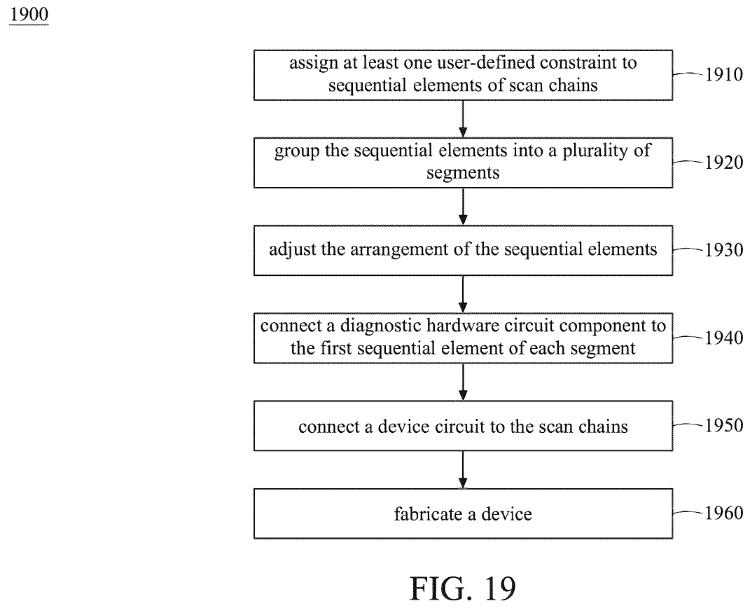

FIG. 19 is a flowchart illustrating an exemplary method 1900 for manufacturing a device, e.g., device 1400-1800, in accordance with various embodiments of the present disclosure. The example method 1900 will now be described with further reference to FIGS. 1-18 for ease of understanding. It is understood that the method 1900 is applicable to structures other than those of FIGS. 1-18. Further, it is understood that additional operations can be provided before, during, and after the method 1900, and some of the operations described below can be replaced or eliminated, in an alternative embodiment of the method 1900.

In operation 1910, the device manufacturing system assigns at least one user-defined constraint to sequential elements (FF1-FF17). In certain embodiments, these constraints include “don't move” constraints for sequential elements that have their positions remain fixed within the scan chain (e.g., 1710-1750) and “don't touch” constraints for sequential elements that remain free of connection to the diagnostic hardware circuit (e.g., diagnostic hardware circuit 160 of FIG. 1).

Next, in operation 1920, the device manufacturing system groups the sequential elements of each scan chain 1710-1750 into a plurality of segments (e.g., segments 1760, 1770) based on an area budget, such as 1% of the total area, that defines the segment length (i.e., the number of sequential elements per segment). Subsequently, in operation 1930, the device manufacturing system adjusts the arrangement of the sequential elements within the scan chains. For example, if the first sequential element of a segment has a “don't touch” constraint, it is swapped with another sequential element. The swapped sequential element may be from the same segment, a different segment of the same scan chain, or a different scan chain, provided it is not assigned a “don't move” constraint or a “don't touch” constraint. After the adjustment, in operation 1940, the device manufacturing system connects circuit components (e.g., multiplexers MUX1-MUX4) of the diagnostic hardware circuit 160 to the first sequential element of each segment in the scan chains, except for those sequential element designated with “don't move” or “don't touch” constraints. In operation 1950, the device manufacturing system then connects a device circuit (e.g., device circuit 130 of FIG. 1) to the scan chains. Finally, in operation 1960, the device manufacturing system fabricates the device 1400-1800.

In an embodiment, a device operates in functional and diagnostic modes and comprises input and output terminals, a scan chain, and a device circuit. The input terminal receives test pattern data provided by diagnostic software tool. The output terminal provides diagnostic output data. The scan chain is connected between the input and output terminals and includes a plurality of sequential elements and a diagnostic hardware circuit. The sequential elements are connected in series and grouped into a plurality of segments. The diagnostic hardware circuit includes a plurality of circuit components, each connected to one sequential element of a respective segment. The diagnostic hardware circuit identifies a defective segment of the scan chain during the diagnostic mode. The test pattern data is serially shifted through the scan chain to isolate the faulty sequential element of the defective segment during the diagnostic mode. The device circuit is connected to the scan chain, performs one or more circuit functions, and generates functional data that is sequentially shifted through the scan chain during the functional mode.

In another embodiment, a device operates in functional and diagnostic modes and comprises input and output terminals, a bi-directional scan chain, and a device circuit. The input terminal receives test pattern data. The output terminal provides diagnostic output data. The bi-directional scan chain is connected between the input and output terminals and includes a plurality of sequential elements and a diagnostic hardware circuit. The sequential elements are connected in series and grouped into a plurality of segments. The segments include first and second segments. The diagnostic hardware circuit includes a plurality of circuit components and a feedback loop. Each circuit component is connected to one sequential element of a respective segment. The feedback loop connects an output of the second segment to an input of the segment. The diagnostic hardware circuit performs a forward-shift diagnosis and a backward-shift diagnosis. The forward-shift diagnosis propagates the test pattern data from a first sequential element to a last sequential element of the scan chain to identify a defective segment of the scan chain during the diagnostic mode. The backward-shift diagnosis propagates the test pattern data from the last sequential element to the first sequential element to isolate the faulty sequential element of the defective segment during the diagnostic mode. The device circuit is connected to the scan chain, performs one or more circuit functions, and generates functional data that is sequentially shifted through the scan chain during the functional mode.

In another embodiment, a method for diagnosing faults in a device comprises performing a coarse-grain diagnosis on a scan chain of the device to identify a defective segment and performing a fine-grain diagnosis on the identified defective segment to pinpoint one or more faulty sequential elements of the defective segment by serially shifting test pattern data through the scan chain. The scan chain includes a plurality of sequential elements and a diagnostic hardware circuit. The sequential elements are grouped into segments. The diagnostic hardware circuit includes a plurality of circuit components, each connected to a first sequential element of a respective segment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device configured to operate in functional and diagnostic modes, the device comprising:
an input terminal configured to receive test pattern data provided by a diagnostic software tool;
an output terminal configured to provide diagnostic output data;
a scan chain connected between the input terminal and the output terminal, the scan chain including:
a plurality of sequential elements connected in series and grouped into a plurality of segments; and
a diagnostic hardware circuit including a plurality of circuit components, each connected to one sequential element of a respective segment, wherein:
the diagnostic hardware circuit is configured to identify a defective segment of the scan chain during the diagnostic mode; and
the test pattern data is serially shifted through the scan chain to isolate the faulty sequential element of the defective segment during the diagnostic mode; and
a device circuit connected to the scan chain and configured to perform one or more circuit functions and to generate functional data that is sequentially shifted through the scan chain during the functional mode.

2. The device of claim 1, wherein the sequential element is the first sequential element.

3. The device of clam 1, wherein:
the diagnostic hardware circuit is configured to diagnose a stuck-at-1 fault in one or more sequential elements of the scan chain during the diagnostic mode;
a test pattern data includes a sequence of logical lows is serially shifted through the scan chain;
the expected output pattern is compared with the actual output pattern at the output terminal; and
a discrepancy between the expected and actual output patterns indicates the presence of a stuck-at-1 fault in one or more sequential elements.

4. The device of claim 1, wherein:
the diagnostic hardware circuit is configured to diagnose a transition delay fault in one or more sequential elements of the scan chain during the diagnostic mode;
a test pattern data is serially shifted through the scan chain to induce a rising transition into the scan chain;
the expected transitions are captures and compared with the actual transitions at the output terminal; and
it is determined whether a sequential element exhibits a delayed response, indicating a transition delay fault.

5. The device of claim 1, wherein:
the diagnostic hardware circuit is configured to diagnose a stuck-at-0 fault in one or more sequential elements of the scan chain during the diagnostic mode;
a test pattern data includes a sequence of logical highs is serially shifted through the scan chain;
the expected output pattern is compared with the actual output pattern at the output terminal; and
a discrepancy between the expected and actual output patterns indicates the presence of a stuck-at-0 fault in one or more sequential elements.

6. The device of claim 1, wherein:
the diagnostic hardware circuit is configured to diagnose a transition delay fault in one or more sequential elements of the scan chain during the diagnostic mode;
a test pattern data is serially shifted through the scan chain to induce a falling transition into the scan chain;
the expected transitions are captures and compared with the actual transitions at the output terminal; and
it is determined whether a sequential element exhibits a delayed response, indicating a transition delay fault.

7. The device of claim 1, wherein the scan chain is configured to switch between functional and diagnostic modes in response to a select signal.

8. A device configured to operate in functional and diagnostic modes, the device comprising:
an input terminal configured to receive test pattern data;
an output terminal configured to provide diagnostic output data;
a bi-directional scan chain connected between the input terminal and the output terminal, the bi-directional scan chain including:
a plurality of sequential elements connected in series and grouped into a plurality of segments, wherein the plurality of segments include a first segment and a second segment that follows the first segment; and
a diagnostic hardware circuit including:
a plurality of circuit components, each connected to one sequential element of a respective segment; and
a feedback loop connecting an output of the second segment to an input of the first segment, wherein the diagnostic hardware circuit is configured to perform:
a forward-shift diagnosis to propagate the test pattern data from a first sequential element to a last sequential element of the scan chain to identify a defective segment of the scan chain during the diagnostic mode; and
a backward-shift diagnosis to propagate the test pattern data from the last sequential element to the first sequential element to isolate the faulty sequential element of the defective segment during the diagnostic mode; and
a device circuit connected to the scan chain and configured to perform one or more circuit functions and to generate functional data that is sequentially shifted through the scan chain during the functional mode.

9. The device of claim 8, wherein the one sequential element is the first sequential element.

10. The device of clam 8, wherein:
the forward-shift diagnosis is configured to identify a defective segment of the scan chain;
a test pattern data is serially shifted from the first sequential element to the last sequential element of the scan chain;
the output terminal captures the resulting response of the scan chain;
the expected output pattern is compared with the actual output pattern to detect a discrepancy; and
a defective segment is identified when the discrepancy indicates a deviation from the expected propagation of the test pattern data through the scan chain.

11. The device of claim 8, wherein:
the backward-shift diagnosis is performed after identifying a defective segment;
a test pattern data is serially shifted in reverse order, from the last sequential element to the first sequential element of the scan chain;
the diagnostic hardware circuit isolates the faulty sequential element within the defective segment by analyzing the response at the output terminal; and
a sequential element is determined to be faulty if its actual output response deviates from the expected test pattern data during backward shifting.

12. The device of claim 8, wherein the diagnostic hardware circuit is configured to diagnose stuck-at faults.

13. The device of claim 8, wherein the diagnostic hardware circuit is configured to diagnose transition delay faults.

14. The device of claim 8, wherein the scan chain is configured to switch between functional and diagnostic modes in response to a select signal.

15. A method for diagnosing faults in a device, the method comprising:
performing a coarse-grain diagnosis on a scan chain of the device to identify a defective segment, wherein the scan chain includes:
a plurality of sequential elements grouped into segments; and
a diagnostic hardware circuit including a plurality of circuit components, each connected to a first sequential element of a respective segment; and
performing a fine-grain diagnosis on the identified defective segment to pinpoint one or more faulty sequential elements of the defective segment by serially shifting test pattern data through the scan chain.

16. The method of claim 15, wherein performing the coarse-grain diagnosis includes serially shifting first test pattern data through the scan chain and performing the fine-grain diagnosis includes serially shifting second test pattern data through the scan chain.

17. The method of claim 15, wherein performing the coarse-grain diagnosis includes serially shifting first test pattern data from a first sequential element to a last sequential element of the scan chain and performing the fine-grain diagnosis includes serially shifting second test pattern data from the last sequential element to the first sequential element.

18. The method of claim 15, further comprising serially shifting functional data through the scan chain.

19. The method of claim 15, further comprising diagnosing the scan chain for stuck-at faults.

20. The method of claim 15, further comprising diagnosing the scan chain for transition delay faults.
